(19) United States
(12) Patent Application Publication
(10) Pub. No.: US 2024/0112888 A1
(43) Pub. Date: Apr. 4, 2024

(54) In-Situ Adsorbate Formation for Dielectric Etch

(71) Applicant: Tokyo Electron Limited, Tokyo (JP)

(72) Inventors: Du Zhang, Albany, NY (US); Yu-Hao Tsai, Albany, NY (US); Masahiko Yokoi, Miyagi (JP); Mingmei Wang, Albany, NY (US); Yoshihide Kihara, Miyagi (JP)

(21) Appl. No.: 17/937,179

(22) Filed: Sep. 30, 2022

(51) Int. Cl. H01J 37/32; H01L 21/311

(52) U.S. Cl. CPC H01J 37/3244; H01L 21/31116; H01L 21/31144; H01J 37/32091; H01J 37/32724; H01J 2237/2001; H01J 2237/332; H01J 2237/3341; H01J 2237/3345; H01J 2237/3346

(57) ABSTRACT

A method of processing a substrate that includes: flowing an etch gas, O₂, and an adsorbate precursor into a plasma processing chamber that is configured to hold the substrate including a silicon-containing dielectric layer and a patterned mask layer, the etch gas including hydrogen and fluorine; generating a plasma in the plasma processing chamber while flowing the etch gas, O₂, and the adsorbate precursor, the adsorbate precursor being oxidized to form an adsorbate; and patterning, with the plasma, the silicon-containing dielectric layer on the substrate, where the adsorbate forms a sidewall passivation layer.

### TECHNICAL FIELD

The present invention relates generally to methods of processing a substrate, and, in particular embodiments, to neutral adsorption enhancement via in-situ adsorbate formation for dielectric etch.

### BACKGROUND

Generally, a semiconductor device, such as an integrated circuit (IC) is fabricated by sequentially depositing and patterning layers of dielectric, conductive, and semiconductor materials over a substrate to form a network of electronic components and interconnect elements (e.g., transistors, resistors, capacitors, metal lines, contacts, and vias) integrated in a monolithic structure. Many of the processing steps used to form the constituent structures of semiconductor devices are performed using plasma processes.

The semiconductor industry has repeatedly reduced the minimum feature sizes in semiconductor devices to a few nanometers to increase the packing density of components. Accordingly, the semiconductor industry increasingly demands plasma processing technology to provide processes for patterning features with accuracy, precision, and profile control, often at atomic scale dimensions. Meeting this challenge along with the uniformity and repeatability needed for high volume IC manufacturing requires further innovations of plasma processing technology.

### SUMMARY

In accordance with an embodiment of the present invention, a method of processing a substrate that includes: flowing an etch gas, O₂, and an adsorbate precursor into a plasma processing chamber that is configured to hold the substrate including a silicon-containing dielectric layer and a patterned mask layer, the etch gas including hydrogen and fluorine; generating a plasma in the plasma processing chamber while flowing the etch gas, O₂, and the adsorbate precursor, the adsorbate precursor being oxidized to form an adsorbate; and patterning, with the plasma, the silicon-containing dielectric layer on the substrate, where the adsorbate forms a sidewall passivation layer.

In accordance with an embodiment of the present invention, a method of processing a substrate that includes: flowing, into a plasma processing chamber, an etchant including hydrogen and fluorine, O₂, and an adsorbate precursor, the adsorbate precursor including PH3, B2H6, SixHy, H2S, or NH3; generating a plasma in the plasma processing chamber while flowing the etchant, O₂, and the adsorbate precursor, the adsorbate precursor being oxidized to form an adsorbate including P, B, Si, S, or N; and forming a recess in a silicon-containing dielectric layer of the substrate by exposing the substrate to the plasma in the plasma processing chamber, the recess having an aspect ratio of at least 50:1, where the adsorbate forms a sidewall passivation layer in the recess.

In accordance with an embodiment of the present invention, a method of processing a substrate that includes: depositing an organic layer over a silicon-containing dielectric layer of a substrate; patterning the organic layer by a halogen-free plasma etch process; and patterning the silicon-containing dielectric layer by a halogen-based plasma etch process using the patterned organic layer as an etch mask, the halogen-based plasma etch process including generating a halogen-containing plasma from a gas mixture including a halogen-containing etch gas in a plasma processing chamber, flowing O₂ and an adsorbate precursor into the plasma processing chamber, the adsorbate precursor including PH₃, B₂H₆, SiₓH_{y}, H₂S, or NH₃, where the adsorbate precursor is oxidized to form an adsorbate including P, B, Si, S, or N under the halogen-containing plasma, and forming a recess in the silicon-containing dielectric layer of the substrate by exposing the substrate to the halogen-containing plasma in the plasma processing chamber, the recess having an aspect ratio of at least 50:1, where the adsorbate forms a sidewall passivation layer in the recess.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1C illustrate cross sectional views of a substrate during an example process of semiconductor fabrication comprising a plasma etch process to form a high aspect ratio (HAR) feature on the substrate in accordance with various embodiments, wherein FIG. 1A illustrates an incoming substrate comprising a dielectric layer and a patterned hardmask layer, FIG. 1B illustrates the substrate during the formation of the HAR feature by the plasma etch process, and FIG. 1C illustrates the substrate after completing the plasma etch process;

FIGS. 2A-2B illustrate cross sectional views of a substrate during the plasma etch process, wherein FIG. 2A illustrates the substrate where etchant species causing lateral etching, and FIG. 2B illustrates the substrate where a passivation layer preventing lateral etching;

FIG. 3A-3C illustrate schematic surface structures with various adsorbates on silicon oxide, wherein FIG. 3A illustrates H₃PO₄ adsorption, FIG. 3B illustrates HF adsorption, and FIG. 3C illustrates HF—H₃PO₄ co-adsorption;

FIGS. 4A-4C illustrate process flow diagrams of methods of semiconductor fabrication comprising a plasma etch process to form HAR features in accordance with various embodiments, wherein FIG. 4A illustrates an embodiment, FIG. 4B illustrates an alternate embodiment, and FIG. 4C illustrates yet another embodiment; and

FIG. 5 illustrates a plasma system for performing a process of semiconductor fabrication in accordance with various embodiments.

### DETAILED DESCRIPTION OF ILLUSTRATIVE EMBODIMENTS

This application relates to fabrication of semiconductor devices, for example, integrated circuits comprising semiconductor devices, and more particularly to high capacity three-dimensional (3D) memory devices, such as a 3D-NAND (or vertical-NAND), 3D-NOR, or dynamic random access memory (DRAM) device. The fabrication of such devices may generally require forming conformal, high aspect ratio (HAR) features (e.g., a contact hole) of a circuit element. Features with aspect ratio (ratio of height of the feature to the width of the feature) higher than 50:1 are generally considered to be high aspect ratio features, and in some cases fabricating a higher aspect ratio such as 100:1 may be desired for advanced 3D semiconductor devices. In such applications, HAR features may be formed in a dielectric layer (e.g., silicon oxide, silicon nitride, or oxide/nitride layer stack) by a highly anisotropic plasma etch process with high fidelity. However, conventional HAR etch methods may usually comprise tens and sometimes hundreds of processing steps, which thereby complicates the process optimization and etch throughput. A simple yet effective HAR process may therefore be desired. Embodiments of the present application disclose methods of fabricating HAR features by a plasma etch process based on a combination of halogen-based etch chemistry and in-situ neutral adsorbate formation. By increasing the amount of neutrals in the plasma, the methods may advantageously enhance the etch rate. Further, the neutral adsorbate may also provide sidewall passivation that improve the anisotropy of the plasma etch process. The inventors of this disclosure also identified that co-adsorption of two types of adsorbate (e.g., HF and H₃PO₄) may be thermodynamically favorable, which may advantageously benefit the effect of neutrals on the etch rate and sidewall passivation. While some adsorbate species (e.g., H₂O) may require a low temperature (e.g., below −50° C.) for effective sidewall passivation, the methods in various embodiments may advantageously be applied for in-situ adsorbate formation of species (e.g., H₃PO₄) that does not require such a low temperature. Consequently, the methods disclosed in this application may enable a new, cost-effective HAR dielectric etch process. In various embodiments, the methods enable in-situ formation of nonvolatile adsorbate species by flowing an adsorbate precursor (e.g., PH₃) and an oxidant (e.g., O₂) to a plasma processing chamber. In certain embodiments, other types of adsorbates comprising other elements such as B, S, Si, and/or N may also be used.

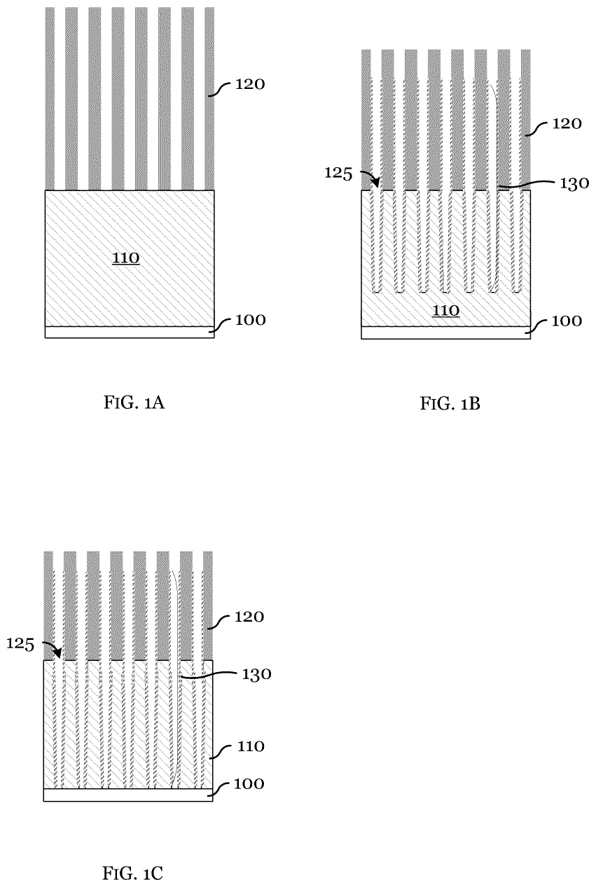

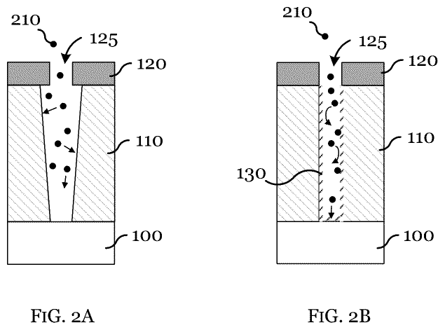

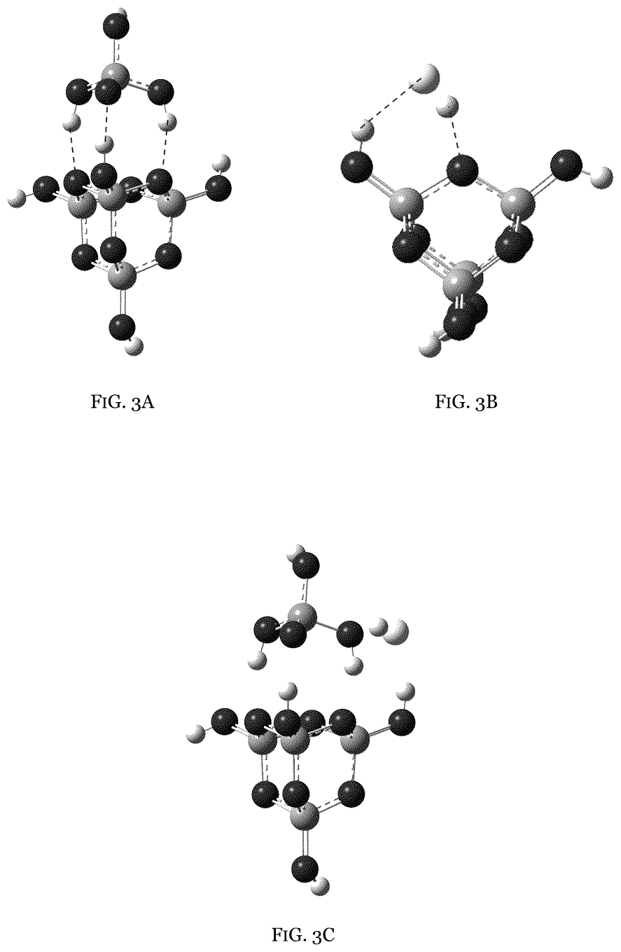

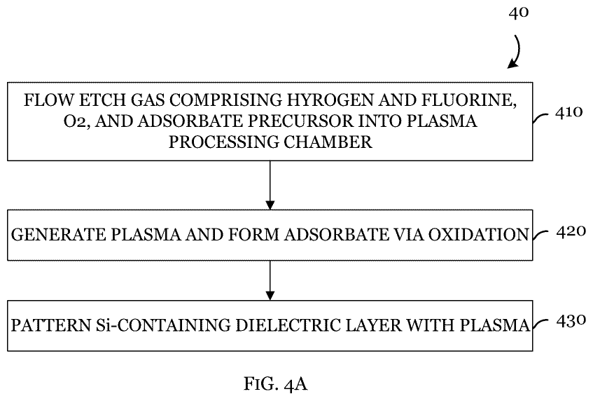

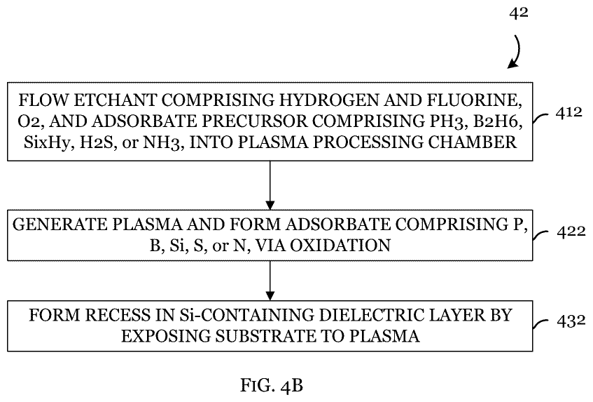

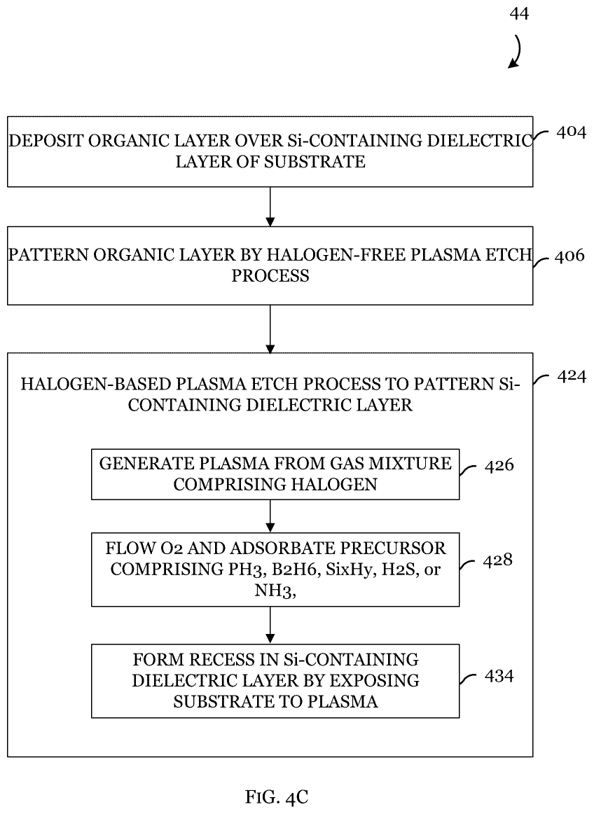

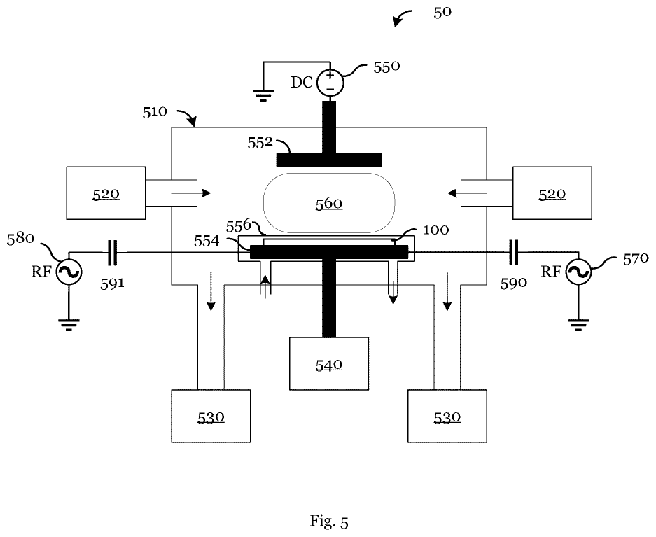

In the following, an exemplary plasma etch process to form a high aspect ratio (HAR) feature is described in accordance with various embodiments referring to FIGS. 1A-1C. The effect of sidewall passivation by a passivation layer is then described referring to FIGS. 2A-2B. Subsequently, different modes of adsorption are compared in FIGS. 3A-3C in terms of simulated energy of adsorption. Example process flow diagrams are then illustrated in FIG. 4A-4C. FIG. 5 provides an example capacitively coupled plasma (CCP) system for performing a process of semiconductor fabrication in accordance with various embodiments. All figures are drawn for illustration purpose only and not to scale, including the aspect ratios of features.

FIGS. 1A-1C illustrate cross sectional views of a substrate 100 during an example process of semiconductor fabrication comprising a plasma etch process to form a HAR feature on the substrate in accordance with various embodiments.

FIG. 1A illustrates an incoming substrate 100 comprising a dielectric layer 110 and a patterned hardmask layer 120.

In one or more embodiments, the substrate 100 may be a silicon wafer, or a silicon-on-insulator (SOI) wafer. In certain embodiments, the substrate may comprise a silicon germanium wafer, silicon carbide wafer, gallium arsenide wafer, gallium nitride wafer and other compound semiconductors. In other embodiments, the substrate comprises heterogeneous layers such as silicon germanium on silicon, gallium nitride on silicon, silicon carbon on silicon, as well layers of silicon on a silicon or SOI substrate.

In various embodiments, the substrate 100 is a part of a semiconductor device, and may have undergone a number of steps of processing following, for example, a conventional process. For example, the semiconductor structure may comprise a substrate 100 in which various device regions are formed. At this stage, the substrate 100 may include isolation regions such as shallow trench isolation (STI) regions as well as other regions formed therein.

The dielectric layer 110 may be formed over the substrate 100. In various embodiments, the dielectric layer 110 is a target layer that is to be patterned into one or more high aspect ratio (HAR) features. In certain embodiments, the HAR feature being etched into the dielectric layer 110 may be a contact hole, slit, or other suitable structures comprising a recess. In certain embodiments, the dielectric layer 110 may be a silicon oxide layer. In alternate embodiments, the dielectric layer 110 may comprise silicon nitride, silicon oxynitride, or an O/N/O/N layer stack (stacked layers of oxide and nitride). The dielectric layer 110 may be deposited using an appropriate technique such as vapor deposition including chemical vapor deposition (CVD), physical vapor deposition (PVD), atomic layer deposition (ALD), as well as other plasma processes such as plasma enhanced CVD (PECVD) and other processes. In one embodiment, the dielectric layer 110 has a thickness between 1 μm and 10 μm. In another embodiment, the dielectric layer 110 may comprise a layer stack with each layer of the stack having a thickness between 50 nm and 2.5 μm.

Still referring to FIG. 1A, the patterned hardmask layer 120 is formed over the dielectric layer 110. In various embodiments, the patterned hardmask layer 120 may comprise amorphous carbon layer (ACL). In one or more embodiments, the patterned hardmask layer 120 may comprise spin-on carbon, tungsten carbide, boron carbide, or other suitable carbon-containing mask materials. The patterned hardmask layer 120 may be formed by first depositing a hardmask layer using, for example, an appropriate spin-coating technique or a vapor deposition technique such as chemical vapor deposition (CVD), physical vapor deposition (PVD), atomic layer deposition (ALD), as well as other plasma processes such as plasma enhanced CVD (PECVD) and other processes. The deposited hardmask layer may then be patterned using a lithography process and an anisotropic etch process, for example, using oxygen-based etch chemistry. The relative thicknesses of the patterned hardmask layer 120 and the dielectric layer 110 may have any suitable relationship. For example, the patterned hardmask layer 120 may be thicker than the dielectric layer 110, thinner than the dielectric layer 110, or the same thickness as the dielectric layer 110. In certain embodiments, the patterned hardmask layer 120 has a thickness between 1 μm and 4 μm. In one embodiment, the patterned hardmask layer 120 comprises amorphous carbon layer (ACL) and has a thickness of 2.5 μm and a critical dimension (CD) of 75 nm, although in other embodiments, the thickness and the CD of the patterned hardmask layer 120 may have any suitable values, respectively.

The patterned hardmask layer 120 and/or the dielectric layer 110 may be collectively considered as a part of the substrate 100. Further, the substrate 100 may also comprise other layers. For example, for the purpose of patterning the hardmask layer, a tri-layer structure comprising a photoresist layer, SiON layer, and optical planarization layer (OPL) may be present.

Fabricating the HAR feature in the dielectric layer 110 may be performed by a plasma etch process using a combination of gases in accordance with various embodiments. A process gas may comprise a halogen-containing etch gas, an oxidant (e.g., O₂), and an adsorbate precursor.

In various embodiments, the etch gas may comprise hydrogen and fluorine, for example, hydrogen fluoride (HF). The HF species and/or other fluorine-containing species may serve as etchant species for etching the dielectric layer 110.

In certain embodiments, HF in the process gas may be less than 70 vol % of the total gas flow. In one or more embodiments, HF in the process gas may be less than 50 vol %, or in another embodiment, less than 10%. Alternately, the process gas may be HF-free. In certain embodiments, the process gas may contain little to no HF, but HF may be formed in-situ under the presence of a plasma form a reaction between a fluorine-containing gas and a hydrogen-containing gas in the etch gas. In one embodiment, the process gas may comprise a fluorocarbon and a hydrogen-containing gas (e.g., CF₄ and H₂). In another embodiment, the process gas may comprise non-carbon fluorine-containing gas and a hydrogen-containing gas (e.g., NF₃ and H₂, SF₆ and H₂, PF₃ and H₂, or PF₅ and H₂).

In various embodiments, the etch gas may comprise a hydrofluorocarbon, a combination of a hydrocarbon and a fluorine-containing gas, or a combination of a fluorocarbon and a hydrogen-containing gas. In certain embodiments, one or more fluorocarbons may be used as a primary etch gas. For example, a saturated fluorocarbon, an unsaturated fluorocarbon, or a combination thereof may be included in a process gas. In this disclosure, an unsaturated fluorocarbon refers to any compound comprising carbon and fluorine with at least one carbon-carbon double bond (C═C bond) or triple bond (CC bond), and a saturated fluorocarbon refers to any compound comprising carbon and fluorine without any C═C bond or CC bond. In certain embodiments, the unsaturated fluorocarbon may comprise hexafluorobutadiene (C₄F₆), hexafluoro-2-butyne (C₄F₆), or hexafluorocyclobutene (C₄F₆), and the saturated fluorocarbon may comprise octafluoropropane (C₃F₈), perfluorobutane (C₄F₁₀), or perflenapent (C₅F₁₂). In various embodiments, other gases such as a noble gas and/or a balancing agent may also be added. For example, in certain embodiments, argon (Ar) and dioxygen (O₂) may be included as the noble gas and the balancing agent, respectively. In alternate embodiments, the combination of gases may further comprise a third fluorocarbon. In one embodiment, the third fluorocarbon may be octafluorocyclobutane (C₄F₈), octafluoro-2-butene (C₄F₈), hexafluoropropylene (C₃F₆), carbon tetrafluoride (CF₄), or fluoroform (CHF₃). While above examples are primarily fluorine-based etch gases, other halogen-containing gases may also be used (e.g., BCl₃, Cl₂, and HBr).

The adsorbate precursor and the oxidant (e.g., O₂) may be included in a process gas such that, under a plasma condition, an adsorbate may be formed in a plasma processing chamber via oxidation. In various embodiments, the adsorbate may comprise phosphorous. In one or more embodiments, the adsorbate formed in the plasma processing chamber may comprise phosphoric acid (H₃PO₄). The inventors of this disclosure identified that H₃PO₄ may be an effective adsorbate that provides sidewall passivation. However, H₃PO₄ is nonvolatile and it is therefore impractical to directly deliver it in a gas phase to the plasma processing chamber. In various embodiments, the methods deliver an adsorbate precursor to enable in-situ formation of the adsorbate in the plasma processing chamber. The in-situ formation of adsorbate such as H₃PO₄ can overcome the issue of nonvolatility. Accordingly, the adsorbate precursor may comprise phosphorous. Examples of the P-containing adsorbate precursor include PH₃ and PCl₃.

In other embodiments, the adsorbate may comprise other elements such as B, S, Si, and/or N, and the adsorbate precursor may accordingly comprise these elements. In certain embodiment, the adsorbate precursor may comprise B₂H₆, SiₓH_{y}, H₂S, or NH₃. Accordingly, the adsorbate formed in the plasma processing chamber may comprise boric acid, silicic acid, sulfuric acid, nitric acid, or similar acidic molecules comprising B, S, Si, and/or N. These acidic molecules may be exposed to behave similarly to phosphoric acid (H₃PO₄) and thereby function as an effective adsorbate for sidewall passivation.

Further, in various embodiments, these adsorbates may primarily be neutral species in a plasma system and effective in surface modification/activation during a plasma etch process such as reactive ion etching (RIE). By increasing the amount of neutrals in the plasma, the methods may advantageously enhance the etch rate.

The inventors of this disclosure identified that a specific additive gas combination of an oxidant (e.g., O₂) and an adsorbate precursor that may be oxidized (e.g., PH₃) may be critical to enable in-situ adsorbate formation and thereby effective sidewall passivation and etch rate enhancement. The presence of oxygen species under the presence of a plasma enables and facilitates the oxidation reaction of the adsorbate precursor. In certain embodiment, the plasma etch process may use a combination of gases comprising an etch gas and an additive gas mixture comprising O₂ and PH₃. Further, the inclusion of a hydrogen-containing gas (e.g., H₂) may be beneficial in generating reactive ion species in the plasma by facilitating dissociation of molecules, which may enhance the etch rate. Accordingly, in another embodiment, the additive gas mixture may comprise O₂, H₂, and PH₃. In yet another embodiment, the additive gas mixture may comprise O₂, H₂, and B₂H₆, O₂, H₂, and SiₓH_{y}, O₂, H₂, and H₂S, O₂, H₂, and NH₃, O₂, H₂, and CO₂, or O₂, H₂, and CO. In certain embodiments, more than one type of adsorbate may be used. In one or more embodiments, an additional adsorbate (e.g., H₂O) may be formed in the plasma processing chamber, in addition to the adsorbate comprising P, B, S, Si, and/or N.

All gases may be flowed continuously at a steady flow rate, or in certain embodiments, their flow rates may be individually changed during the plasma etch process. Further, various gas pulsing schemes may be applied in the methods. For example, a portion of the process gas (e.g., O₂ and the adsorbate precursor) may be intermittently flowed into the plasma processing chamber with gas pulsing. Such gas pulsing may enable a fine turning of the concentration the adsorbate in the plasma processing chamber and thereby the degree of passivation.

In certain embodiments, a ratio of a flow rate of the halogen-containing etch gas (e.g., CF₄) to a flow rate of the adsorbate precursor (e.g., PH₃) may be between 100:1 and 1:1. In one or more embodiments, the ratio of the flow rate may be between 100:1 and 10:1, and in another embodiment, between 100:1 and 20:1.

In certain embodiments, a ratio of a flow rate of the oxidant (e.g., O₂) to a flow rate of the adsorbate precursor (e.g., PH₃) may be between 100:1 and 1:1. In one or more embodiments, the ratio of the flow rate may be between 100:1 and 10:1, and in another embodiment, between 100:1 and 20:1.

In certain embodiments, a ratio of a flow rate of the halogen-containing etch gas to a flow rate of the oxidant (e.g., O₂) may be between 100:1 and 1:1. In one or more embodiments, the ratio of the flow rate may be between 100:1 and 10:1, and in another embodiment, between 100:1 and 20:1.

In various embodiments, during the plasma etch process, the substrate temperature may be kept above 0° C., for example between 0° C. and 50° C. In most methods using HF as a primary etch gas and/or certain adsorbate species (e.g., H₂O), a low-temperature condition (e.g., <0° C.) may be required for sufficient etch performance, primarily because the physisorption of HF may occur only at very low temperatures. Using new types of adsorbate species in place of or in addition to HF, the methods may advantageously eliminate the low-temperature requirement from the plasma etch process for HAR feature in dielectric materials. As a result, the etch rate may be improved by controlling the temperature in a wider range according to the methods.

FIG. 1B illustrates the substrate 100 during the formation of the HAR feature by the plasma etch process.

In FIG. 1B, the high aspect ratio (HAR) feature is being formed as recesses 125 in the dielectric layer 110 by the plasma etch process. As illustrated in FIG. 1B, by the plasma etch process, the recesses 125 may be formed straight and uniformly across the substrate 100 with little to no bowing. Bowing refers to the deviation of a perfectly straight recess from a purely anisotropic profile to a recess having outward curvature. Bowing may generally occur near the top of sidewalls of the etch target (e.g., the dielectric layer 110), and may be caused by the bending of incident ion trajectories of ions used during the plasma etching process. Bowing may be eliminated or minimized by the sidewall passivation in the recess 125. Such passivation may be achieved by the passivation layer 130 of adsorbate species. In one or more embodiments, the passivation layer 130 may also include a deposit of polymeric species derived from a carbon-containing gas in the etch gas (e.g., saturated and/or unsaturated fluorocarbons).

Also in the example of FIG. 1B, a sufficient etch rate enables the recesses 125 to have a high aspect ratio in a short process time compared to conventional HAR etch methods. Although not wishing to be limited by any theory, the presence of the adsorbate at etch front (e.g., an exposed top surface of the dielectric layer 110) may catalyze the reaction of the etchant (e.g., F-containing species) with the dielectric layer 110, which therefore increase the etch rate. Simultaneously, due to a good selectivity to the hardmask during the plasma etch process, only a small fraction of the hardmask may be consumed.

The recesses 125 may be in any shapes and structures, including a contact hole, slit, or other suitable structures comprising a recess useful for semiconductor device fabrication. In various embodiments, the features defined by the recesses 125 has a critical dimension (CD) of 200 nm or less. In certain embodiments, the CD may be between 50 nm and 200 nm. For example, the feature may comprise a slit with a CD of about 150 nm. In alternate embodiments, the recesses 125 may comprise a hole that has a top opening with a diameter of 80 nm or less.

FIG. 1C illustrates the substrate 100 after completing the plasma etch process.

Continuing the plasma etch process, the recesses 125 illustrated in FIG. 1B may be extended further by etching through the entire thickness of the dielectric layer 110 and reach to the top surface of the substrate 100 as illustrated in FIG. 1C. The plasma etch process in accordance with various embodiments may provide a good selectivity to silicon (Si) in addition to the hardmask. Accordingly, the plasma etch may be selective to the substrate 100 comprising silicon and the formation of the recesses 125 may advantageously stop at the top surface of the substrate 100.

In various embodiments, a RF pulsing at a kHz range may be used to power the plasma. Using the RF pulsing may help generating high energetic ions (>keV) in the plasma for the plasma etch process, while reducing a charging effect. The charging effect during a process is a phenomenon where electrons build charge on insulating materials (e.g., silicon oxide of the dielectric layer 110) creating a local electric field that may steer positive ions to the sidewalls and cause a lateral etching. Therefore, fine tuning the power conditions of the plasma etch process may also be important to minimize the widening of critical dimension (CD) of the high aspect ratio (HAR) feature. In certain embodiments, a moderate duty ratio between 40% to 80% may be used. In one embodiment, a bias power of 18 kW may be pulsed at a frequency of 5 kHz with a duty ratio of 60%.

In certain embodiments, the plasma etch process may be advantageously performed as a continuous process with a process time of 60 min or less to form a high aspect ratio (HAR) feature with an aspect ratio of 100:1 or higher. In other embodiments, the plasma etch process may be applied as a part of a cyclic plasma process comprising various steps (e.g., etch step, deposition step, flash step, and by-product control step).

In various embodiments, process parameters may be selected to optimize the characteristics of the high aspect ratio (HAR) feature considering various factors comprising controlled level of deposition, selectivity to the hardmask, sidewall passivation in the HAR feature, and good critical dimension uniformity (CDU) among others. The process parameters may comprise gas selection, gas flow rates, pressure, temperature, process time, and plasma conditions such as source power, bias power, RF pulsing conditions.

Further processing may follow conventional processing, for example, by removing the patterned hardmask layer 120, followed by filling the recess 125 with a conductive material to form a HAR conductive feature (e.g., contact plugs for memory arrays). For example, the conductive material may be copper formed using electroplating. However, any suitable conductive material and deposition method may be used. Excess conductive material may then be removed from the top surface of the dielectric layer 110 using a planarization process (e.g., a chemical-mechanical planarization).

FIGS. 2A-2B illustrate cross sectional views of a substrate 100 during the plasma etch process. FIG. 2A illustrates the substrate 100 where etchant species causing lateral etching, and FIG. 2B illustrates the substrate 100 where a passivation layer 130 preventing lateral etching. The structure of the substrate 100 may be identical to those illustrated in FIGS. 1A-1C, and thus will not be repeated.

In FIG. 2A, the substrate 100 is illustrated after performing a plasma etch process in the absence of sidewall passivation of a recess 125. In this example, when etchants 210 (e.g., F-containing species) in the plasma impinge on the sidewalls of the recess 125, they may cause lateral etching, which may then lead to the widening/bowing of the recesses 125. Since the degree of lateral etching may vary at different depth of the recess 125, the sidewall of the recess 125 may not be straight. It may be tapered as illustrated in FIG. 2A and/or bowed. Consequently, the HAR feature of the dielectric layer 110 may suffer line wiggling and/or pattern collapse. To avoid such issues, in various embodiments, the sidewall passivation may be enabled and improved by adding a hydrogen-containing gas in the process gas.

In FIG. 2B, the substrate 100 is illustrated after performing a plasma etch process with the sidewall passivation of a recess 125. The sidewall passivation may be achieved by forming the passivation layer 130 comprising the adsorbate (e.g., H₃PO₄). The passivation layer 130 protects the sidewalls of the recess 135 from the etchants 210.

FIG. 3A-3C illustrate schematic surface structures with various adsorbates on silicon oxide.

The inventors of this disclosure identified a P-containing adsorbate may be advantageous in providing sidewall passivation without low temperature conditions through quasi-continuum density functional theory (QC-DFT) simulations. Furthermore, a synergetic enhancement of energy of adsorption is demonstrated for HF—H₃PO₄ co-adsorption. In FIG. 3A, an adsorption of H₃PO₄ onto a hydrophilic surface of SiO₂ is illustrated, and the simulated energy of adsorption (E_{ads}) is −0.8837 eV. In FIG. 3B, an adsorption of HF onto a hydrophilic surface of SiO₂ is illustrated, and the simulated E_{ads} is −0.4920 eV. In FIG. 3C, a co-adsorption of HF and H₃PO₄ onto a hydrophilic surface of SiO₂ is illustrated, and the simulated E_{ads} is −1.4519 eV. The results are summarized in Table 1. The simulated E_{ads} for the co-adsorption (−1.4519 eV) is greater than the sum of the two simulated E_{ads} for HF and H₃PO₄ (−1.3757 eV), indicating the synergetic enhancement of energy of adsorption. This result demonstrates that the presence of HF or H₃PO₄ during the plasma etch process may advantageously enhance the adsorption of a second adsorbate type, H₃PO₄ or HF, respectively. Accordingly, the methods may benefit by including these two types of adsorbate for a better effect of adsorbate (e.g., etch rate and/or sidewall passivation).

TABLE 1
Simulated energy of adsorption on SiO₂

| Adsorbate | E_{ads} [eV] |
|---|---|
| H₃PO₄ | −0.8837 |
| HF | −0.4920 |
| HF + H₃PO₄ | −1.4519 |

FIGS. 4A-4C illustrate process flow diagrams of methods of semiconductor fabrication comprising a plasma etch process to form a HAR feature on a substrate comprising a material layer in accordance with various embodiments. The process flow can be followed with the figures discussed above (e.g., FIGS. 1A-1C) and hence will not be described again.

In FIG. 4A, in accordance with some embodiments, a process flow 40 may start with flowing an etch gas, dioxygen (O₂), and an adsorbate precursor (e.g., PH₃) into a plasma processing chamber (block 410). Next, a plasma may be generated in the plasma processing chamber (block 420), where the adsorbate precursor is oxidized to form an adsorbate (e.g., H₃PO₄). A plasma etch process may then be performed using the plasma to pattern a silicon-containing dielectric layer of a substrate provided in the plasma processing chamber with the plasma (block 430, FIGS. 1A-1C), where the adsorbate forms a sidewall passivation layer.

In FIG. 4B, in accordance with alternate embodiments, a process flow 42 may start with flowing an etchant comprising hydrogen and fluorine, dioxygen (O₂), and an adsorbate precursor comprising PH₃, B₂H₆, SiₓH_{y}, H₂S, or NH₃ (block 412). Next, a plasma may be generated in the plasma processing chamber while flowing the etchant, O₂, and the adsorbate precursor, where the adsorbate precursor is oxidized to form an adsorbate comprising P, B, Si, S, or N (block 422). Subsequently, the substrate may be exposed to the plasma to form a recess in a silicon-containing dielectric layer of the substrate, where the adsorbate forms a sidewall passivation layer in the recess (block 432, FIGS. 1A-1C).

In FIG. 4C, in accordance with yet other embodiments, a process flow 44 may start with depositing an organic layer over a silicon-containing dielectric layer of a substrate (block 404), followed by patterning the organic layer using a halogen-free plasma etch process (block 406, FIG. 1A). Next, a halogen-based plasma etch process may be performed to pattern the silicon-containing dielectric layer using the patterned organic layer as an etch mask (block 424, FIGS. 1B-1C). The halogen-based plasma etch process may start with generating a halogen-containing plasma from a gas mixture comprising a halogen-containing etch gas in a plasma processing chamber (block 426), followed by flowing dioxygen (O₂) and an adsorbate precursor comprising PH₃, B₂H₆, SiₓH_{y}, H₂S, or NH₃ into the plasma processing chamber (block 428), where the adsorbate precursor is oxidized to form an adsorbate comprising P, B, Si, S, or N under the halogen-containing plasma. Subsequently, the substrate may be exposed to the halogen-containing plasma in the plasma processing chamber to form a high aspect ratio (HAR) recess in the silicon-containing dielectric layer of the substrate (block 434), where the adsorbate forms a sidewall passivation layer in the recess.

FIG. 5 illustrates a plasma processing system 50 for performing a process of semiconductor fabrication in accordance with various embodiments.

For illustrative purposes, FIG. 5 illustrates a substrate 100 placed on a substrate holder 554 (e.g., a circular electrostatic chuck (ESC)) inside a plasma processing chamber 510 near the bottom. The substrate 100 may be optionally maintained at a desired temperature using a heater/cooler 556 that surrounds the substrate holder 554. The temperature of the substrate 100 may be maintained by a temperature controller 540 connected to the substrate holder 554 and the heater/cooler 556. The ESC may be coated with a conductive material (e.g., a carbon-based or metal-nitride based coating) so that electrical connections may be made to the substrate holder 554.

As illustrated in FIG. 5, the substrate holder 554 may be a bottom electrode of the plasma processing chamber 510. In the illustrative example in FIG. 5, the substrate holder 554 is connected to two RF-bias power sources, 570 and 580 through blocking capacitors 590 and 591. In some embodiment, a conductive circular plate inside the plasma processing chamber 510 near the top is the top electrode 552. In FIG. 5, the top electrode 552 is connected to a DC power source 550 of the plasma processing system 50.

The gases may be introduced into the plasma processing chamber 510 by a gas delivery system 520. The gas delivery system 520 comprises multiple gas flow controllers to control the flow of multiple gases into the chamber. Each of the gas flow controllers of the gas delivery system 520 may be assigned for each of fluorocarbons, noble gases, and/or balancing agents. In some embodiments, optional center/edge splitters may be used to independently adjust the gas flow rates at the center and edge of the substrate 100.

The RF-bias power sources 570 and 580 may be used to supply continuous wave (CW) or pulsed RF power to sustain the plasma, such as a plasma 560. The plasma 560, shown between the top electrode 552 and the bottom electrode (also the substrate holder 554), exemplifies direct plasma generated close to the substrate 100 in the plasma processing chamber 510 of the plasma processing system 50. Etching may be performed by exposing the substrate 100 to the plasma 560 while powering the substrate holder 554 with RF-bias power sources 570, 580 and optionally the top electrode 552 with the DC power source 550.

The configuration of the plasma processing system 50 described above is by example only. In alternative embodiments, various alternative configurations may be used for the plasma processing system 50. For example, inductively coupled plasma (ICP) may be used with RF source power coupled to a planar coil over a top dielectric cover, the gas inlet and/or the gas outlet may be coupled to the upper wall, etc. In various embodiments, the RF power, chamber pressure, substrate temperature, gas flow rates and other plasma process parameters may be selected in accordance with the respective process recipe. In some embodiments, the plasma processing system 50 may be a resonator such as a helical resonator.

Although not described herein, embodiments of the present invention may be also applied to remote plasma systems as well as batch systems. For example, the substrate holder may be able to support a plurality of wafers that are spun around a central axis as they pass through different plasma zones.

Example embodiments of the invention are summarized here. Other embodiments can also be understood from the entirety of the specification as well as the claims filed herein.

Example 1. A method of processing a substrate that includes: flowing an etch gas, O₂, and an adsorbate precursor into a plasma processing chamber that is configured to hold the substrate including a silicon-containing dielectric layer and a patterned mask layer, the etch gas including hydrogen and fluorine; generating a plasma in the plasma processing chamber while flowing the etch gas, O₂, and the adsorbate precursor, the adsorbate precursor being oxidized to form an adsorbate; and patterning, with the plasma, the silicon-containing dielectric layer on the substrate, where the adsorbate forms a sidewall passivation layer.

Example 2. The method of example 1, where the adsorbate includes H₃PO₄, and where the adsorbate precursor includes PH₃.

Example 3. The method of one of examples 1 or 2, where the adsorbate includes boron.

Example 4. The method of one of examples 1 to 3, where the adsorbate includes silicon.

Example 5. The method of one of examples 1 to 4, where the adsorbate includes sulfur.

Example 6. The method of one of examples 1 to 5, where the adsorbate includes nitrogen.

Example 7. The method of one of examples 1 to 6, where the etch gas is HF-free.

Example 8. The method of one of examples 1 to 7, where the etch gas is a gas mixture including includes dihydrogen (H₂) and a fluorocarbon.

Example 9. The method of one of examples 1 to 8, where the etch gas is a gas mixture including includes dihydrogen (H₂) and NF₃, H₂ and SF₆, H₂ and PF₃, or H₂ and PF₅.

Example 10. The method of one of examples 1 to 9, where the silicon-containing dielectric layer includes silicon oxide or silicon nitride.

Example 11. The method of one of examples 1 to 10, where a ratio of a gas flow rate of O₂ to a gas flow rate of the adsorbate precursor is between 100:1 and 1:1.

Example 12. The method of one of examples 1 to 11, further including maintaining a temperature of the substrate at between 0° C. and 50° C.

Example 13. A method of processing a substrate that includes: flowing, into a plasma processing chamber, an etchant including hydrogen and fluorine, O₂, and an adsorbate precursor, the adsorbate precursor including PH₃, B₂H₆, SiₓH_{y}, H₂S, or NH₃; generating a plasma in the plasma processing chamber while flowing the etchant, O₂, and the adsorbate precursor, the adsorbate precursor being oxidized to form an adsorbate including P, B, Si, S, or N; and forming a recess in a silicon-containing dielectric layer of the substrate by exposing the substrate to the plasma in the plasma processing chamber, the recess having an aspect ratio of at least 50:1, where the adsorbate forms a sidewall passivation layer in the recess.

Example 14. The method of example 13, where the substrate further includes a patterned amorphous carbon layer (ACL) over the silicon-containing dielectric layer, the patterned ACL being an etch mask during forming the recess.

Example 15. The method of one of examples 13 or 14, where the recess defines a feature having a critical dimension between 50 nm and 200 nm.

Example 16. The method of one of examples 13 to 15, further including maintaining a temperature of the substrate at between 0° C. and 50° C.

Example 17. A method of processing a substrate that includes: depositing an organic layer over a silicon-containing dielectric layer of a substrate; patterning the organic layer by a halogen-free plasma etch process; and patterning the silicon-containing dielectric layer by a halogen-based plasma etch process using the patterned organic layer as an etch mask, the halogen-based plasma etch process including generating a halogen-containing plasma from a gas mixture including a halogen-containing etch gas in a plasma processing chamber, flowing O₂ and an adsorbate precursor into the plasma processing chamber, the adsorbate precursor including PH₃, B₂H₆, SiₓH_{y}, H₂S, or NH₃, where the adsorbate precursor is oxidized to form an adsorbate including P, B, Si, S, or N under the halogen-containing plasma, and forming a recess in the silicon-containing dielectric layer of the substrate by exposing the substrate to the halogen-containing plasma in the plasma processing chamber, the recess having an aspect ratio of at least 50:1, where the adsorbate forms a sidewall passivation layer in the recess.

Example 18. The method of example 17, where the halogen-containing plasma is a capacitively coupled plasma (CCP).

Example 19. The method of one of examples 17 or 18, where flowing O₂ and the adsorbate precursor includes flowing O₂ and the adsorbate precursor intermittently.

Example 20. The method of one of examples 17 to 19, further including maintaining a temperature of the substrate at between 0° C. and 50° C. during the halogen-based plasma etch process.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of processing a substrate, the method comprising:
flowing an etch gas, O₂, and an adsorbate precursor into a plasma processing chamber that is configured to hold the substrate comprising a silicon-containing dielectric layer and a patterned mask layer, the etch gas comprising hydrogen and fluorine;
generating a plasma in the plasma processing chamber while flowing the etch gas, O₂, and the adsorbate precursor, the adsorbate precursor being oxidized to form an adsorbate; and
patterning, with the plasma, the silicon-containing dielectric layer on the substrate, wherein the adsorbate forms a sidewall passivation layer.

2. The method of claim 1, wherein the adsorbate comprises H₃PO₄, and wherein the adsorbate precursor comprises PH₃.

3. The method of claim 1, wherein the adsorbate comprises boron.

4. The method of claim 1, wherein the adsorbate comprises silicon.

5. The method of claim 1, wherein the adsorbate comprises sulfur.

6. The method of claim 1, wherein the adsorbate comprises nitrogen.

7. The method of claim 1, wherein the etch gas is HF-free.

8. The method of claim 7, wherein the etch gas is a gas mixture comprising comprises dihydrogen (H₂) and a fluorocarbon.

9. The method of claim 7, wherein the etch gas is a gas mixture comprising comprises dihydrogen (H₂) and NF₃, H₂ and SF₆, H₂ and PF₃, or H₂ and PF₅.

10. The method of claim 1, wherein the silicon-containing dielectric layer comprises silicon oxide or silicon nitride.

11. The method of claim 1, wherein a ratio of a gas flow rate of O₂ to a gas flow rate of the adsorbate precursor is between 100:1 and 1:1.

12. The method of claim 1, further comprising maintaining a temperature of the substrate at between 0° C. and 50° C.

13. A method of processing a substrate, the method comprising:
flowing, into a plasma processing chamber, an etchant comprising hydrogen and fluorine, O₂, and an adsorbate precursor, the adsorbate precursor comprising PH₃, B₂H₆, SiₓH_{y}, H₂S, or NH₃;
generating a plasma in the plasma processing chamber while flowing the etchant, O₂, and the adsorbate precursor, the adsorbate precursor being oxidized to form an adsorbate comprising P, B, Si, S, or N; and
forming a recess in a silicon-containing dielectric layer of the substrate by exposing the substrate to the plasma in the plasma processing chamber, the recess having an aspect ratio of at least 50:1, wherein the adsorbate forms a sidewall passivation layer in the recess.

14. The method of claim 13, wherein the substrate further comprises a patterned amorphous carbon layer (ACL) over the silicon-containing dielectric layer, the patterned ACL being an etch mask during forming the recess.

15. The method of claim 13, wherein the recess defines a feature having a critical dimension between 50 nm and 200 nm.

16. The method of claim 13, further comprising maintaining a temperature of the substrate at between 0° C. and 50° C.

17. A method of processing a substrate, the method comprising:
depositing an organic layer over a silicon-containing dielectric layer of a substrate;
patterning the organic layer by a halogen-free plasma etch process; and
patterning the silicon-containing dielectric layer by a halogen-based plasma etch process using the patterned organic layer as an etch mask, the halogen-based plasma etch process comprising
generating a halogen-containing plasma from a gas mixture comprising a halogen-containing etch gas in a plasma processing chamber,
flowing O₂ and an adsorbate precursor into the plasma processing chamber, the adsorbate precursor comprising PH₃, B₂H₆, SiₓH_{y}, H₂S, or NH₃, wherein the adsorbate precursor is oxidized to form an adsorbate comprising P, B, Si, S, or N under the halogen-containing plasma, and
forming a recess in the silicon-containing dielectric layer of the substrate by exposing the substrate to the halogen-containing plasma in the plasma processing chamber, the recess having an aspect ratio of at least 50:1, wherein the adsorbate forms a sidewall passivation layer in the recess.

18. The method of claim 17, wherein the halogen-containing plasma is a capacitively coupled plasma (CCP).

19. The method of claim 17, wherein flowing O₂ and the adsorbate precursor comprises flowing O₂ and the adsorbate precursor intermittently.

20. The method of claim 17, further comprising maintaining a temperature of the substrate at between 0° C. and 50° C. during the halogen-based plasma etch process.
